(19) United States
(12) Patent Application Publication
(10) Pub. No.: US 2021/0005545 A1
(43) Pub. Date: Jan. 7, 2021

(54) INTEGRATED DEVICES COMPRISING UNIFORM METAL LAYER THICKNESS ACROSS ONE OR MORE METAL LAYERS

(71) Applicant: QUALCOMM Incorporated, San Diego, CA (US)

(72) Inventors: Kai LIU, San Diego, CA (US); Xia LI, San Diego, CA (US); Bin YANG, San Diego, CA (US)

(21) Appl. No.: 16/503,237

(22) Filed: Jul. 3, 2019

(51) Int. Cl. H01L 23/528; H01L 23/522

(52) U.S. Cl. CPC H01L 23/528; H01L 23/5227; H01L 23/5223

(57) ABSTRACT

An integrated device that includes a substrate, a third plurality of interconnects formed on a third metal layer, a fourth plurality of interconnects formed on a fourth metal layer, at least one dielectric layer formed over the substrate. The third metal layer is located over the substrate. The third metal layer has a third pattern density. The third plurality of interconnects has a third thickness that is approximately the same for all interconnects of the third plurality of interconnects. The fourth metal layer is located over the third metal layer. The fourth metal layer has a fourth pattern density. The fourth pattern density is different than the third pattern density. The fourth plurality of interconnects has a fourth thickness that is approximately the same for all interconnects of the fourth plurality of interconnects.

### FIELD

Various features relate to integrated devices, but more specifically to integrated devices comprising uniform metal layer thickness across one or more metal layers.

### BACKGROUND

A wafer, which is also known as a semiconductor wafer, is a substrate on which integrated devices (e.g., integrated passive devices) are formed. A single wafer may include hundreds of integrated devices or more. A single wafer may be diced or sliced to form the individual integrated devices. Integrated devices have very complicated designs and very small interconnects. As the sizes of the integrated devices have gotten smaller and smaller, it has become very important to be able to precisely control the sizes of the interconnects in the integrated devices.

As such, there is a need for integrated devices with precise interconnects sizes, and a method for fabricating such integrated devices.

### SUMMARY

Various features relate to integrated devices, but more specifically to integrated devices comprising uniform metal layer thickness across several metal layers.

One example provides an integrated device that includes a substrate, a third plurality of interconnects formed on a third metal layer, a fourth plurality of interconnects formed on a fourth metal layer, at least one dielectric layer formed over the substrate. The third metal layer is located over the substrate. The third metal layer has a third pattern density. The third plurality of interconnects has a third thickness that is approximately the same for all interconnects of the third plurality of interconnects. The fourth metal layer is located over the third metal layer. The fourth metal layer has a fourth pattern density. The fourth pattern density is different than the third pattern density. The fourth plurality of interconnects has a fourth thickness that is approximately the same for all interconnects of the fourth plurality of interconnects.

Another example provides an apparatus that includes a substrate; means for capacitance coupled to the substrate; and means for inductance configured to be electrically coupled to the means for capacitance. The means for inductance includes a third plurality of interconnects formed on a third metal layer. The third metal layer is located over the substrate. The third plurality of interconnects has a third thickness. The third metal layer has a third pattern density. The means for inductance includes a fourth plurality of interconnects formed on a fourth metal layer. The fourth metal layer is located over the third metal layer. The fourth plurality of interconnects has a fourth thickness. The fourth metal layer has a fourth pattern density. The fourth pattern density is different than the third pattern density.

Another example provides a wafer that includes a plurality of first integrated devices and a plurality of second integrated devices. The first integrated device has a first design. Each first integrated device includes a first plurality of third interconnects formed on a third metal layer of the wafer, and a first plurality of fourth interconnects formed on a fourth metal layer of the wafer. The second integrated device has a second design that is different than the first design. Each second integrated device includes a second plurality of third interconnects formed on the third metal layer of the wafer, and a second plurality of fourth interconnects formed on the fourth metal layer of the wafer. The first plurality of third interconnects for each of the first integrated devices, and the second plurality of third interconnects for each of the second integrated devices, have a third thickness that is approximately the same. The third metal layer of the first integrated device has a different design than the third metal layer of the second integrated device.

Another example provides a device that includes a board, a first integrated device coupled to the board, and a second integrated device coupled to the board. The first integrated device includes a first substrate, a first plurality of third interconnects formed on a third metal layer of the first integrated device, and a first plurality of fourth interconnects formed on a fourth metal layer on the first integrated device. The second integrated device includes a second substrate, a second plurality of third interconnects formed on a third metal layer of the second integrated device, and a second plurality of fourth interconnects formed on a fourth metal layer of the second integrated device. The first plurality of third interconnects for the first integrated device, and the second plurality of third interconnects for second integrated device, have a third thickness that is approximately the same. The third metal layer of the first integrated device has a different design than the third metal layer of the second integrated device.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a top plan view of a wafer comprising a plurality of integrated devices.

FIG. 2 illustrates a profile side view of an integrated device comprising at least one capacitor and at one inductor.

FIG. 3 illustrates a profile side view of another integrated device comprising at least one capacitor and at one inductor.

FIG. 4 illustrates a profile side view of another integrated device comprising at least one capacitor and at one inductor.

FIG. 5 illustrates views of an inductor formed primarily on one metal layer of an integrated device.

FIG. 6 illustrates views of an inductor formed on at least two metal layers of an integrated device.

FIG. 7 illustrates a top plan view of a filter that includes an inductor formed primarily on one metal layer of the filter.

FIG. 8 illustrates a top plan view of a filter that includes an inductor formed on at least two metal layers of the filter.

FIG. 9 illustrates a graph of inductance values of a first inductor formed on one metal layer and a second inductor formed on two metal layers.

FIG. 10 illustrates a graph of quality factor values of a first inductor formed on one metal layer and a second inductor formed on two metal layers.

FIG. 11 illustrates a top plan view of a wafer comprising a plurality of first integrated devices and a plurality of second integrated devices.

FIG. 12 illustrates a top plan view of filters that includes at least one inductor and at least one capacitor.

FIG. 13 illustrates an exemplary flow diagram of a method for providing uniform metal layer thickness one or more metal layers of an integrated device.

FIG. 14 (comprising FIGS. 14A-14D) illustrates an exemplary sequence for fabricating an integrated device that includes uniform metal layer thickness one or more metal layers.

FIG. 15 illustrates an exemplary flow diagram of a method for fabricating an integrated device that includes several metal layers.

FIG. 16 illustrates various electronic devices that may integrate a die, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes an integrated device that includes a substrate, a third plurality of interconnects formed on a third metal layer, a fourth plurality of interconnects formed on a fourth metal layer, at least one dielectric layer formed over the substrate. The third metal layer is located over the substrate. The third metal layer has a third pattern density. The third plurality of interconnects has a third thickness that is approximately the same for all interconnects of the third plurality of interconnects. The fourth metal layer is located over the third metal layer. The fourth metal layer has a fourth pattern density. The fourth pattern density is different than the third pattern density. The fourth plurality of interconnects has a fourth thickness that is approximately the same for all interconnects of the fourth plurality of interconnects. The third metal layer may be a M3 layer, and the fourth metal layer may be a M4 metal layer. The integrated device may include a first metal layer (e.g., M1 layer) and a second metal layer (e.g., M2 layer). In some implementations, portions of the third plurality of interconnects and portions of the fourth plurality of interconnects define at least one inductor. In some implementations, the integrated device includes at least one capacitor. The integrated device may be configured to operate as a filter (e.g., signal filter). The integrated device may be an integrated passive device (IPD) formed from a wafer.

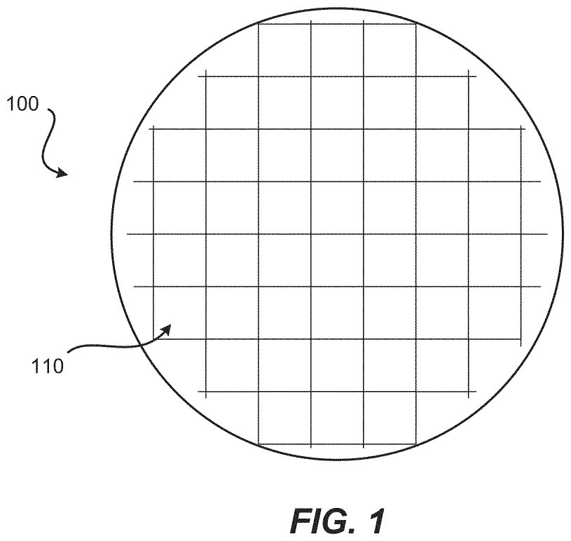

FIG. 1 illustrates a wafer 100 that includes several integrated devices 110. The integrated devices 110 may be integrated passive devices (IPDs) and/or dies. The process of fabricating an integrated device may include fabricating several integrated devices over a substrate (e.g., glass) and singulating (e.g., slicing, dicing) the wafer into individual integrated devices.

As will be further described below, the process of fabricating an integrated device includes a plating process (e.g., electroplating process) to form interconnects in the integrated device. An integrated device includes several metal layers, and each metal layer has one or more interconnects that are formed through a plating process. A plating process involves providing an electrical current, which causes metal to be formed (e.g., deposited, disposed). This electrical current is applied for each metal layer of the integrated device. Typically, the same current density is applied for each metal layer. Thus, the thickness of an interconnect on a metal layer is dependent and/or proportional to the current density (which is measured in amps per square decimeter (ASD)) and how many interconnects are formed on the metal layer. For the same current density, more interconnects on a metal layer means thinner interconnects, while less interconnects on a metal layer means thicker interconnects. Controlling the thickness and size of the interconnects is important as integrated devices become smaller and smaller. This can be very challenging when different metal layers of an integrated device (e.g., die) have different pattern densities. The pattern density (e.g., metal pattern density) of an integrated device (e.g., die) on one metal layer is defined as the planar surface area of the interconnects on an integrated device area (e.g., die area) relative to the total integrated device (e.g., die area) for that layer. For example, if the entire die is covered with metal then the pattern density for that die would be 100%. In another example, if the planar surface area of all the interconnects on a particular die is half of the total possible surface area for that particular die, then the pattern density for that die would be 50%.

Pattern densities (e.g., metal pattern densities) may include low pattern density, medium pattern density and high pattern density. In some implementations, a low pattern density may include a pattern density of about 5% or less. In some implementations, a medium pattern density may include a pattern density in a range of about 10% to 15%. In some implementations, a high pattern density may include a pattern density of about 20% or greater. The above ranges are exemplary. Different implementations may have different range values.

Integrated devices with different pattern densities across one metal layer are problematic because these differences in pattern densities can cause different interconnects thicknesses across a metal layer. As will be further described below, different interconnect thickness for a metal layer may cause performance and reliability issues for the integrated devices.

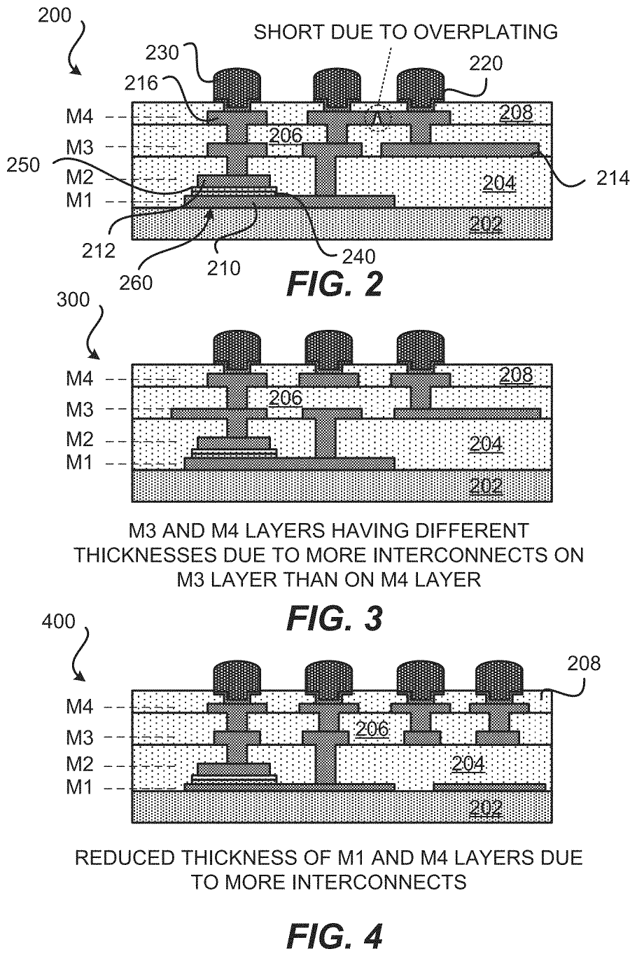

FIG. 2 illustrates a side profile view of an integrated device 200. The integrated device 200 may be an integrated passive device (IPD) (e.g., IPD die) configured to operate as a filter (e.g., means for filtering, means for signal filtering). The integrated device 200 may be a die. The integrated device 200 includes a substrate 202, dielectric layers 204, 206 and 208, a first metal layer 210 (M1), a second metal layer 212 (M2), a third metal layer 214 (M3), a fourth metal layer 216 (M4), an underbump metallization (UBM) layer 220, solder interconnects 230, a metal layer 240, and a high K dielectric layer 250. The substrate 202 may be glass and/or silicon. It is noted that the components shown in the figures of the disclosure are for illustrative purposes and may not be necessarily to scale.

The first metal layer 210, the second metal layer 212, the third metal layer 214 and the fourth metal layer 216 may include interconnects (e.g., traces, pads). In some implementations, at least some of the interconnects on the third metal layer 214 and the fourth metal layer 216 define one or more inductors. An inductor may be a means for inductance. The integrated device 200 may include a capacitor 260. In some implementations, the capacitor 260 may be defined by an interconnect on the first metal layer 210, an interconnect on the second metal layer 212, the metal layer 240 and the high K dielectric layer 250. The capacitor 260 may be a means for capacitance.

FIG. 2 illustrates that the third metal layer 214 (M3) has a higher pattern density than the fourth metal layer 216 (M4). This can cause the fourth metal layer 216 to be over plated, resulting in a short due to interconnects coming in contact with each other, when they are designed not to be touching each other. Thus, an imbalance or difference in pattern densities between metal layers can result in the loss of control in the size and/or shapes interconnects. Similarly, if the third metal layer 214 has a lower pattern density than the fourth metal layer, then the third metal layer may be over plated, resulting in a short due to interconnects coming in contact with each other.

FIG. 3 illustrates another example of an integrated device 300. In this example, the thickness of the interconnects on the third metal layer 214 is less than the thickness of the interconnects on the fourth metal layer 216. This may be due to the fact that the third metal layer 214 has a higher pattern density than the fourth metal layer 216. The lower thickness of the interconnects on the third metal layer 214 is problematic for applications. In addition, thicker interconnects have less DC loss and less radio frequency (RF) loss than thinner interconnects.

FIG. 4 illustrates another example of an integrated device 400. In this example, the thickness of the interconnects on the fourth metal layer 216 is less than the thickness of the interconnects on the third metal layer 214. As mentioned above, the lower thickness of the interconnects on the fourth metal layer 216 is problematic for applications. In addition, thicker interconnects have less DC loss and less radio frequency (RF) loss than thinner interconnects.

Integrated devices are often designed with different pattern densities for different metal layers. This is problematic because the process of fabricating an integrated device uses the same plating current density for the different metal layers. In addition, some wafers may include integrated devices with different designs.

Table 1 illustrates an example of the thicknesses of interconnects for different exemplary pattern densities and plating currents.

TABLE 1
Exemplary Thicknesses for different Metal Pattern
Densities under different plating conditions

| Metal | Plating Current | Plating Current | Pattern |
|---|---|---|---|
| Zone | 5 ASD | 2 ASD | Density |
| First Area in a | 23.78 μm | 20.21 μm | Low Pattern |
| Metal Layer | | | Density Area |
| Second Area in a | 16.80 μm | 16.33 μm | High Pattern |
| Metal Layer | | | Density Area |
| Third Area in a | 20.06 μm | 19.50 μm | Medium Pattern |
| Metal Layer | | | Density Area |

Table 1 illustrates the variances in thicknesses for different interconnects on the same metal layer with different pattern densities. Table 1 illustrates that changing the plating current does not substantially improve the uniformity of the thickness of the interconnects.

### Modifying Pattern of Interconnects on Different Metal Layers

As mentioned above, for a given plating current, the pattern density of a particular layer affects the thickness of interconnects on that particular layer. To provide uniform interconnect thickness within one layer (e.g., M3 or M4), the design of certain components of an integrated device may be modified.

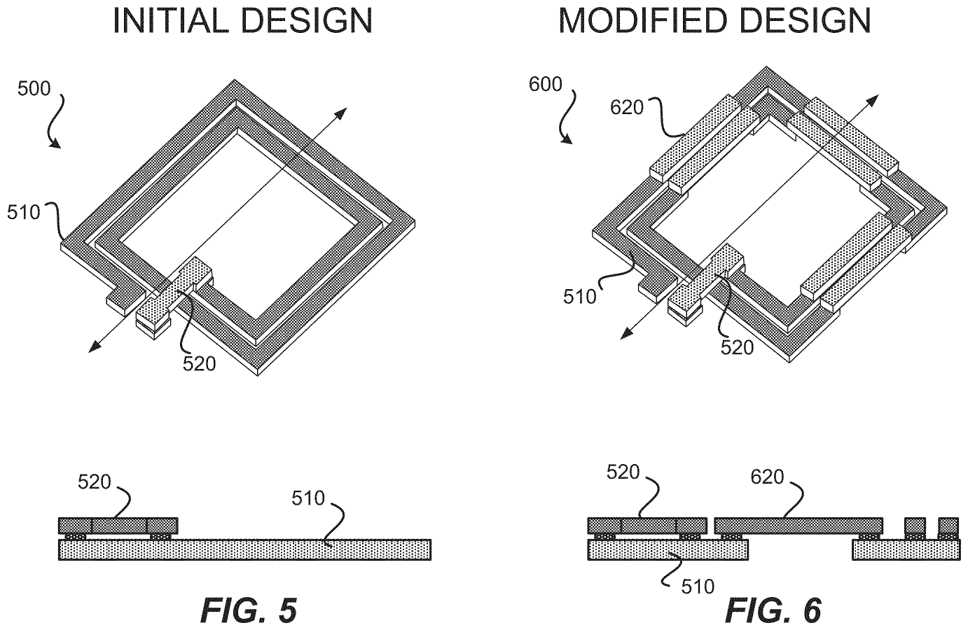

FIG. 5 illustrates views of an inductor 500 that is formed on a metal layer of an integrated device. The inductor 500 may be an initial exemplary design of an inductor. The inductor 500 includes an interconnect 510 and an interconnect 520. The inductor 500 may be formed on a metal layer that has already a lot of interconnects. The interconnect 510 may be on a particular metal layer (e.g., bottom layer), while the interconnect 520 may be on a different layer (e.g., top layer). As shown in FIG. 5, the inductor 500 is substantially (more than 90%) defined by interconnects on one metal layer.

To improve the pattern density of one or more metal layers of an integrated device, parts of the inductor 500 may be relocated to another metal layer. FIG. 6 illustrates views of an inductor 600 that is formed on a two metal layers of an integrated device. The inductor 600 includes the interconnect 510, the interconnect 520, and interconnects 620. The interconnect 510 is on one layer, while the interconnect 520 and interconnects 620 are on another layer. In particular, interconnects 620 replace interconnects which were part of interconnect 510. This modification to the inductor makes it is possible to adjust the pattern density (e.g., metal pattern density) in one layer, by reducing the pattern density of one layer while increasing the pattern density of another layer. FIG. 6 illustrates that there is no separate interconnect (separate from the inductor, or not part of the inductor) that is directly below (or directly above) the interconnects 620. In this example, the inductor 600 is more evenly balanced with respect to where the interconnects are located. It is noted that modifications to the inductor in FIG. 6 is merely exemplary. Other implementations may modify the inductor differently by relocating portions of interconnects differently.

FIGS. 5 and 6 illustrate some interconnects (or portions of interconnects) are relocated from a lower metal layer (e.g., M3) to an upper metal layer (e.g., M4). In some implementations, some interconnects (or portions of interconnects) are relocated from an upper metal layer (e.g., M4) to a lower metal layer (e.g., M3).

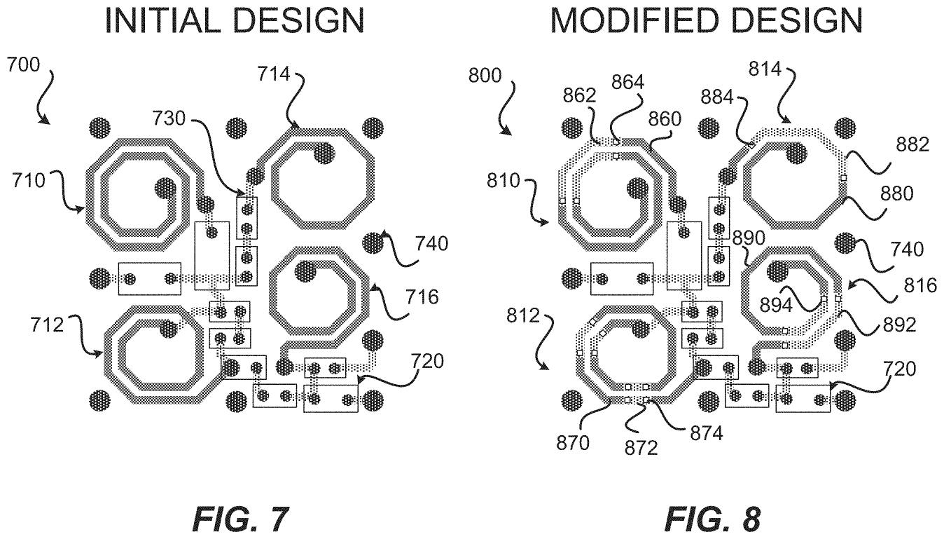

FIGS. 7 and 8 illustrate another example of how interconnects may be relocated on different layers in order to improve the pattern density uniformity on several metal layers. FIG. 7 illustrates a filter 700 that includes several inductors (710, 712, 714, 716) and several capacitors 720. The filter 700 may be implemented as part of an integrated device. The inductors 710, 712, 714 and 716 are each formed and defined by one or more interconnects located on a particular metal layer (e.g., M3 or M4). The filter 700 also includes pads 740 and interconnects 730. The interconnects 730 may be used to electrically couple capacitors to each other and/or to electrically couple an inductor to a capacitor. The interconnects 730 are located another metal layer (e.g., lower metal layer, M2). In some implementations, the capacitors 720 are located on first metal layer and second metal layers of the filter 700. Vias may be used to couple the different metal layers. For example, vias may couple interconnects between the M3 and M4 metal layers. In another example, vias may also couple interconnects between the M2 and M3 metal layers. The size of the vias may vary. The filter 700 may be implemented as part of an integrated device (e.g., integrated passive device). FIG. 7 illustrates that the pattern density on the particular metal layer (e.g., M3) is higher than the pattern density on another meta layer (e.g., M4),

FIG. 8 illustrates a filter 800 that includes inductors that have been modified to include interconnects on several layers. The filter 800 may be implemented as part of an integrated device. In term of functionality, the filter 800 is similar to the filter 700. However, the filter 800 includes inductors with modified interconnect designs. The filter 800 includes several inductors (810, 812, 814, 816) and several capacitors 720. The inductor 810 includes interconnects 860, interconnects 862 and via 864. The interconnects 860 are located on a different metal layer than the interconnects 862. For example, the interconnects 860 may be located on a particular metal layer (e.g., M3), while the interconnects 862 may be located on another metal layer (e.g., M4). The inductor 812 includes interconnects 870, interconnects 872 and via 874. The interconnects 870 are located on a different metal layer than the interconnects 872. For example, the interconnects 870 may be located on a particular metal layer (e.g., M3), while the interconnects 872 may be located on another metal layer (e.g., M4). The inductor 814 includes interconnects 880, interconnects 882 and via 884. The interconnects 880 are located on a different metal layer than the interconnects 882. For example, the interconnects 880 may be located on a particular metal layer (e.g., M3), while the interconnects 882 may be located on another metal layer (e.g., M4). The inductor 816 includes interconnects 890, interconnects 892 and via 894. The interconnects 890 are located on a different metal layer than the interconnects 892. For example, the interconnects 890 may be located on a particular metal layer (e.g., M3), while the interconnects 892 may be located on another metal layer (e.g., M4).

FIG. 8 illustrates that by relocating or moving certain interconnects and/or portions of interconnects to a different metal layer than the initial design, a more balanced pattern density may be achieved for one or more metal layers, resulting in a more uniform metal layer thickness for each metal layer of an integrated device. How many interconnects are relocated and where they are relocated will vary with different implementations.

As an example, for different integrated passive device (IPD) die designs on the same wafer, a certain pattern density (e.g., metal pattern density) for each layer can be targeted. For example, for design of experiment (DOE) purposes (using design variations) on the same wafer, the total metal consumed is about the same for the same circuit schematic (same LC values in schematic, but implemented differently in 3D manner) which the DOE is based on. Therefore, the total density (for M3 and M4 layers together) is about the same for all the design variations. Table 2 below illustrates exemplary modifications for three different die designs on the same wafer.

TABLE 2
Exemplary Modifications to Metal Layers Densities

| | Original | Original | Modified | Modified |
|---|---|---|---|---|
| Die design on | design (M3 | design (M4 | design (M3 | design (M4 |
| same wafer | density) | density) | density) | density) |
| First Die | 4% | 20% | 4% increased | 20% reduced to |
| Design | | | to 8% (+4%) | 16% (−4%) |
| Second Die | 20% | 4% | 20% reduced to | 4% increased |
| Design | | | 8% (−12%) | to 16% (+12%) |
| Third Die | 12% | 12% | 12% reduced to | 12% increased |
| Design | | | 8% (−4%) | to 16% (+4%) |

| | | | |
|---|---|---|---|
| Notes: | Total M3 and M4 density: 24% | Targeting 8% | Targeting 16% |
| | | (⅓ of 24%) | (⅔ of 24%) |

As shown above in Table 2, the modification of the first die design increases the density of the M3 layer by 4%, and decreases the density of the M4 layer by 4%. The modification of the second die design deceases the density of the M3 layer by 12%, and increases the density of the M4 layer by 12%. The modification of the third die design decreases the density of the M3 layer by 4%, and increases the density of the M4 layer by 4%. The end result is that the total density of the M3 and M4 layers for the modified designs is 24%, which is about the same as the total density of the M3 and M4 layers for the original designs. It is noted that Table 2 is merely an example of modifications that may be made to one or more of the die designs. Other implementations, may make different modifications to the die designs that may affect the densities of the M3 and M4 layers.

As will be further described below, it is noted that the different metal layers do not necessarily have to have the exact same pattern density (e.g., metal pattern density) in order to ensure uniform metal layer thickness. The term uniform metal layer thickness means that metal patterns in same layer have approximately the same thickness. Approximately the same thickness may mean that the thicknesses are within 2 micrometers of one another. Approximately the same pattern density (e.g., metal pattern density) may mean that the densities (e.g., metal pattern densities) are within 2% of one another.

Different implementations may implement different uniform metal layer thicknesses. For example, the thickness of interconnects on a particular layer (e.g., 16 μm for M4) of an integrated device may be within about 6 micrometers (μm) of the thickness of interconnects on another layer (e.g., 10 μm for M3) of the integrated device, or vice versa. In some implementations, the pattern density of interconnects on a particular layer (e.g., 16% density for M4 as shown in Table 2) of an integrated device may be more than five percent of the pattern density on another layer (e.g., 8% density for M3 as shown in Table 2) of the integrated device, or vice versa. In some implementations, the thickness of interconnects on two or more metal layers (e.g., M3 and M4) of an integrated device may be about 16 micrometers (μm). The above thicknesses and pattern density parameters may be applicable to any of the integrated devices described in the disclosure.

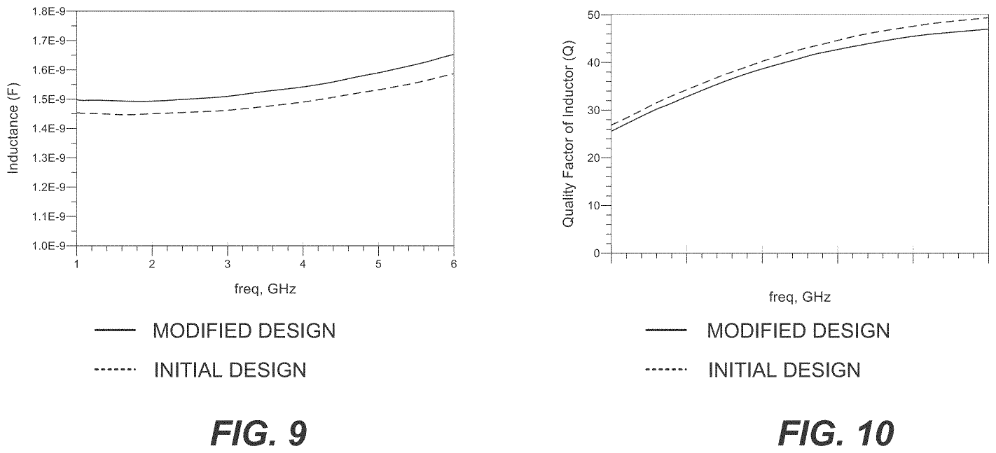

Despite the change in the configuration and design of the inductor(s), to produce a more uniform metal layer thickness, the overall performance of the inductor(s) and/or filter does not change dramatically. FIGS. 9 and 10, respectively show the inductance (F) and the quality factor (Q), of an exemplary initial inductor defined by a single metal layer and an exemplary modified inductor defined on two or more metal layers. As shown in FIGS. 9 and 10, across various frequencies, the inductance and quality factor of the modified inductor is not that much different than the inductance and quality factor of the initial inductor.

Exemplary Wafer Comprising Integrated Devices with Different Designs

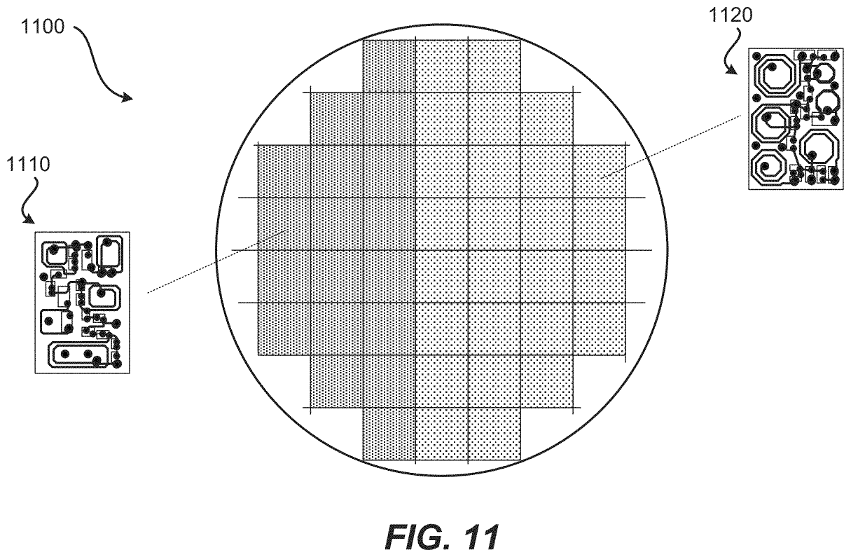

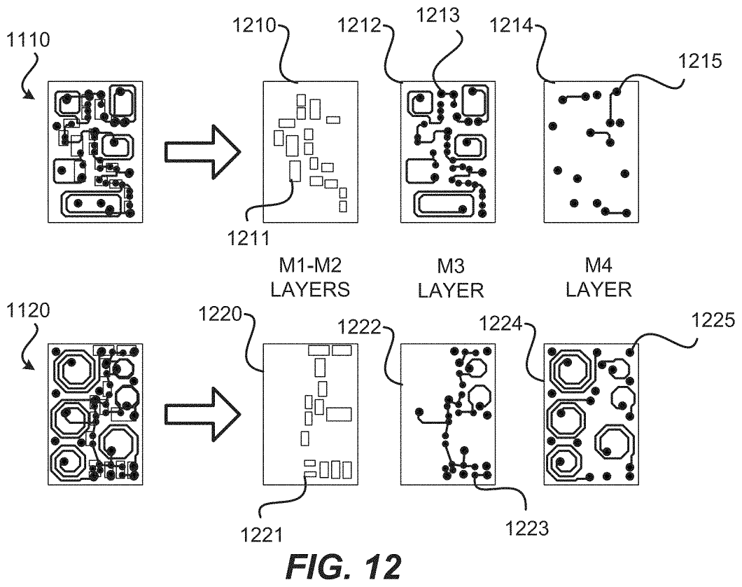

FIG. 11 illustrates a wafer 1100 that includes a plurality of first integrated devices 1110 and a plurality of second integrated devices 1120. As will be further described below in FIG. 12, the first integrated device 1110 has a different design than the second integrated device 1120. For example, the first integrated device 1110 may have different pattern densities than the second integrated device 1120.

FIG. 12 illustrates a plan view of the different layers of the first integrated device 1110 and the second integrated device 1120. The first integrated device 1110 includes metal layers 1210, 1212 and 1214. The metal layer 1210 may represent first and second metal layers (e.g., M1, M2) of the first integrated device 1110. The metal layer 1210 includes capacitors that are defined on the first and second metal layers. The metal layer 1212 includes a third plurality of interconnects 1213 (e.g., traces, pads). At least some of the third plurality of interconnects 1213 define one or more inductors for the first integrated device 1110. The metal layer 1212 may represent a third metal layer (e.g., M3) of the first integrated device 1110. The metal layer 1212 may have a medium or high pattern density. The metal layer 1214 includes a fourth plurality of interconnects 1215 (e.g., traces, pads). Some of the fourth plurality of interconnects 1215 may define one or more inductors for the first integrated device 1110. The metal layer 1214 may represent a fourth metal layer (e.g., M4) of the first integrated device 1110. The metal layer 1214 may have a low pattern density. To provide more uniform metal layer thickness in each layer (e.g., M3 or M4) for both devices 1110 and 1120, some of the interconnects from the metal layer 1212 may be relocated to the metal layer 1214. In some implementations, one or more inductors of the first integrated device 1110 may be defined by interconnects on the third metal layer and the fourth metal layer.

The second integrated device 1120 includes metal layers 1220, 1222 and 1224. The metal layer 1220 may represent first and second metal layers (e.g., M1, M2) of the second integrated device 1120. The metal layer 1220 includes capacitors that are defined on the first and second metal layers. The metal layer 1222 includes a third plurality of interconnects 1223 (e.g., traces, pads). At least some of the third plurality of interconnects 1223 define one or more inductors for the second integrated device 1120. The metal layer 1222 may represent a third metal layer (e.g., M3) of the second integrated device 1120. The metal layer 1222 may have a low or medium pattern density. The metal layer 1224 includes a fourth plurality of interconnects 1225 (e.g., traces, pads). Some of the fourth plurality of interconnects 1225 may define one or more inductors for the second integrated device 1120. The metal layer 1224 may represent a fourth metal layer (e.g., M4) of the second integrated device 1120. The metal layer 1224 may have a medium or high pattern density. To provide more uniform metal layer thickness in each layer (e.g., M3 and M4) for both devices 1110 and 1120, some of the interconnects from the metal layer 1224 may be relocated to the metal layer 1222. In some implementations, one or more inductors of the second integrated device 1120 may be defined by interconnects on the third metal layer and the fourth metal layer.

In addition, and/or in lieu of relocating interconnects on different metal layers to achieve more uniform metal layer thicknesses in each layer, integrated devices with different designs may be fabricated on the same wafer to achieve uniform metal layer thickness in each metal layer of an integrated device.

Since a plating current is applied to the entire wafer, implementing two or more integrated devices with different design on a wafer may produce uniform metal layer thicknesses for individual integrated devices despite the fact that each individual integrated device has a different pattern density for different metal layers. In the example of FIG. 12, it may be possible that the average pattern density of the metal layers 1212 and 1214 is close enough to the average pattern density of the metal layers 1222 and 1224, so that no or little relocation of interconnects is necessary. For example, the average pattern density of the low pattern density of the metal layer 1214 and the high pattern density of the metal layer 1212 of device 1110 may be close enough to the average pattern density of the high pattern density of the metal 1212 and the medium pattern density of the metal layer 1214 of device 1120, to produce uniform metal layer thickness across several metal layers. In one example, the total number of first integrated devices 1110 and the total number of second integrated 1120 on a wafer may be taken into account when calculating and determining the overall pattern density of each metal layer on a wafer. In some implementations, the wafer may be singulated, and the first integrated device 1110 and the second integrated device 1120 may be coupled to a board (e.g., printed circuit board) and integrated into a device (e.g., phone). FIG. 12 illustrates a wafer that include two different integrated devices designs. However, the wafer may include several different designs (e.g., more than two, 3 or more) of an integrated device.

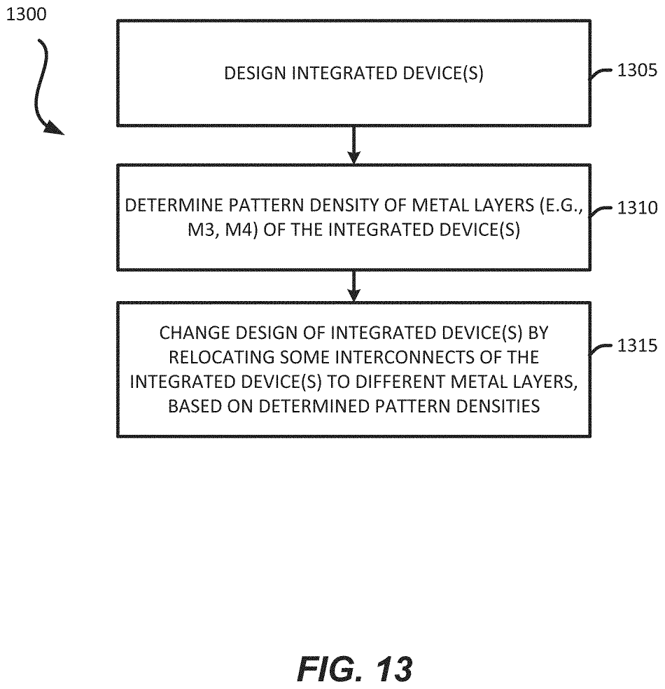

FIG. 13 illustrates an exemplary flow chart of a method 1300 for modifying a design of an integrated device to achieve uniform metal layer thickness across two or more metal layers of an integrated device.

The method designs (at 1305) one or more integrated devices. The integrated device may include one or more inductors and one or more capacitors. The initial design of the one or more inductors may be defined on one metal layer (e.g., M3 or M4) of the integrated device. The initial design of one or more capacitors may be defined on two metal layers (e.g., M1 and M2) of the integrated device. The method may design different integrated devices (e.g., first integrated device, second integrated device) with different configurations for the inductors and/or the capacitors. The integrated device may be configured to operate as a filter.

The method determines (at 1310) the pattern density of each metal layer of the integrated device. Exemplary methods for determining pattern density (e.g., metal pattern density) was previously described above. The pattern density of each metal layer may be determined on an integrated device by integrated device basis, and/or the pattern density of each metal layer may be determined on a wafer basis, based on how many integrated devices (and the different designs of the integrated devices) are to be formed on the wafer.

Once the pattern densities have been measured and determined, the method changes (at 1310) the design of one or more integrated devices, to change the pattern density of or more metal layers of the integrated devices. In some implementations, changing the design of the integrated device may include relocating interconnects from one metal layer to another metal layer. For example, as described above, interconnects for one or more inductors may be relocated to different metal layers. In some implementations, the design of the integrated devices is not changed. Instead, or in addition of the change of the design of the integrated devices, the ratio in the number of different types of integrated devices on a wafer may be changed so that the overall pattern density of each metal layer of the wafer produces a more uniform metal layer thickness.

As an example, suppose the method determines that the pattern density of the M3 layer for one device is about 40% and the pattern density of the M4 layer is 20%. The method may change the design of the integrated device by relocating some interconnects from the M3 layer to the M4 layer, so that the pattern density of the modified M3 layer is now about 25% and the pattern density of the modified M4 layer is about 35%. The modified pattern densities for the M3 layer and the M4 layer may be close enough to other devices in these layers, in order to fabricate a uniform metal layer thickness in the M3 layer and the M4 layer. It is noted that different implementations may make different modifications and changes to how and where interconnects are formed in the integrated device.

Exemplary Sequence for Fabricating an Integrated Device with Uniform Metal Layer Thickness in Each Metal Layer

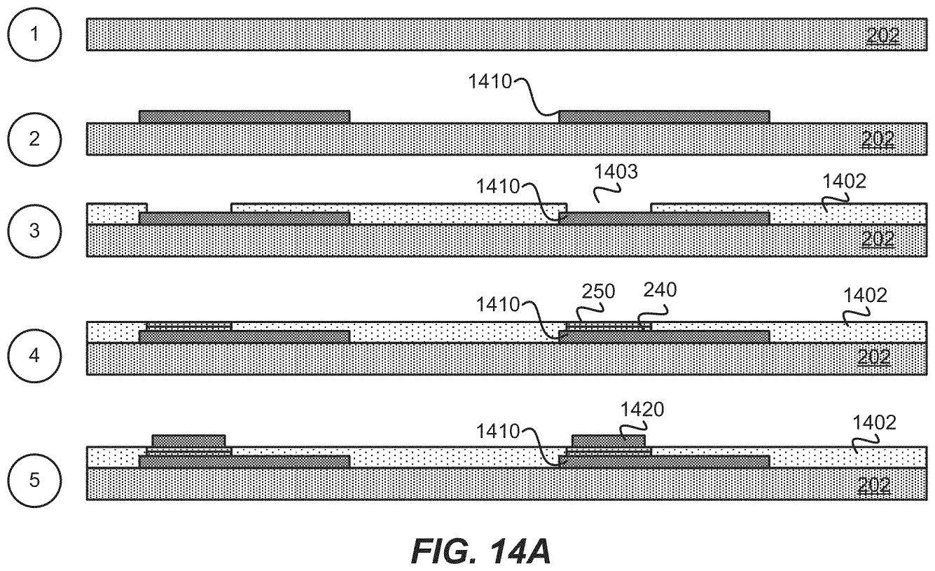

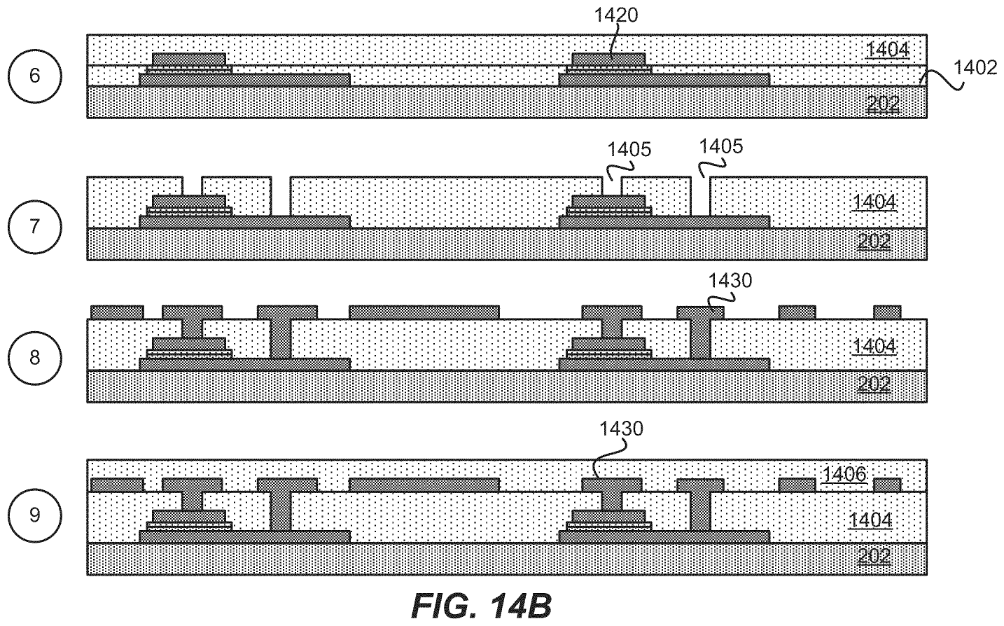

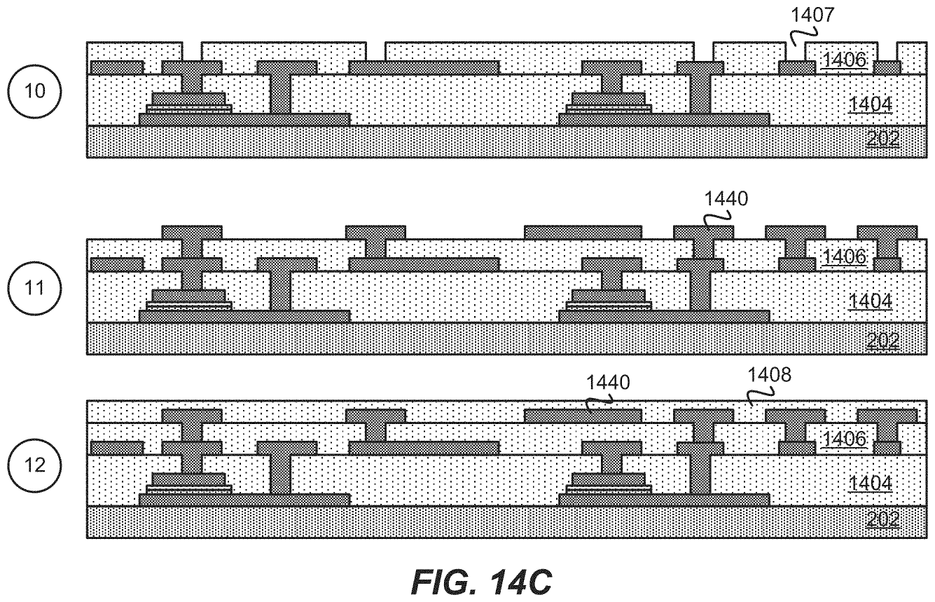

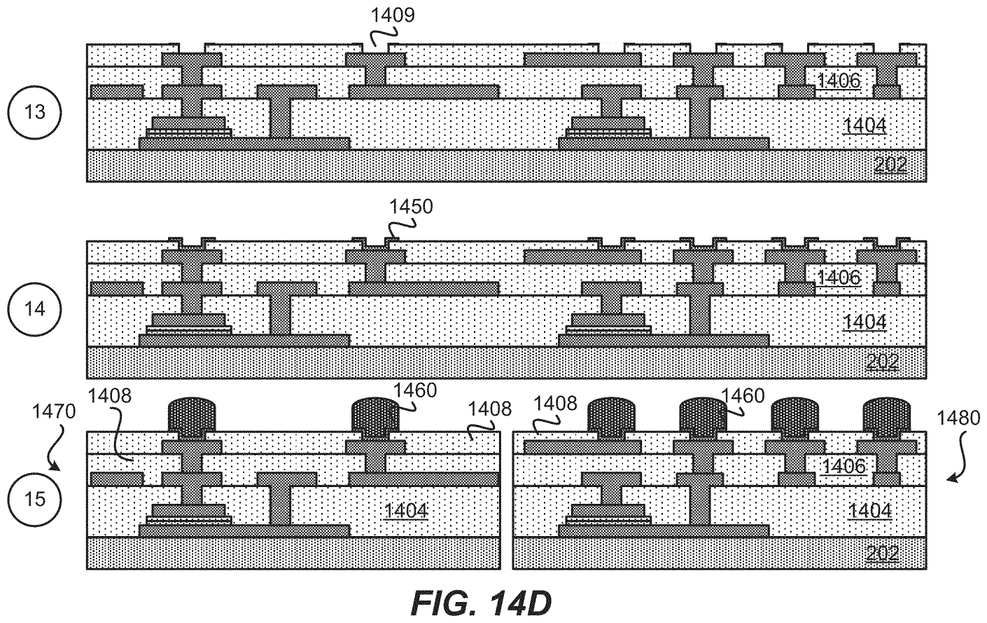

FIG. 14 (which includes FIGS. 14A-14D) illustrates an exemplary sequence for fabricating an integrated device with uniform metal layer thickness in each metal layer. The sequence of FIGS. 14A-14D may be used to fabricate any of the integrated device described in the disclosure.

It should be noted that the sequence of FIGS. 14A-14D may combine one or more stages in order to simplify and/or clarify the sequence for fabricating an integrated device. In some implementations, the order of the processes may be changed or modified. In some implementations, one or more of processes may be replaced or substituted without departing from the spirit of the disclosure. Moreover, it is noted that the sizes, shapes, and dimensions shown are for illustrative purposes and are not necessarily to scale.

Stage 1, as shown in FIG. 14A, illustrates a state after a substrate 202 is provided. The substrate 202 may include glass or silicon. The substrate may be a wafer.

Stage 2 illustrates a state after a first metal layer 1410 is formed (e.g., disposed) over the substrate 202. The first metal layer 1410 may be formed using a plating process. The first metal layer 1410 may include one or more metal layers (e.g., seed layer and metal layer). The first metal layer 1410 may include one or more interconnects. In some implementations, the first metal layer 1410 may have a thickness of 1-2 micrometers (μm).

Stage 3 illustrates a state after a dielectric layer 1402 is formed over the substrate 202 and the first metal layer 1410. In addition, one or more cavities 1403 have been formed in the dielectric layer 1402. An etching process, such as laser ablation or photo etching process may be used to form the cavities 1403.

Stage 4 illustrates a state after a metal layer 240 and a high K dielectric layer 250 have been formed (e.g., disposed) in the cavities 1403 over the first metal layer 1410. The metal layer 240 may be optional.

Stage 5 illustrates a state after a second metal layer 1420 is formed (e.g., disposed) over the high K dielectric layer 250. The second metal layer 1420 may be formed using a plating process. The second metal layer 1420 may include one or more metal layers (e.g., seed layer and metal layer). The second metal layer 1420 may include one or more interconnects. In some implementations, portions of the first metal layer 1410, portions of the second metal layer 1420, the metal layer 240 and the high K dielectric layer 250 may define one or more capacitors. In some implementations, the second metal layer 1420 may have a thickness of 1-2 micrometers (μm).

Stage 6, as shown in FIG. 14B, illustrates a state after a dielectric layer 1404 is formed (e.g., disposed) over the dielectric layer 1402, the first metal layer 1410 and the second metal layer 1420.

Stage 7 illustrates a state after one or more cavities 1405 have been formed in the dielectric layer 1404. It is noted that the dielectric layer 1404 may include the dielectric layer 1402. An etching process, such as laser ablation or photo etching process may be used to form the cavities 1405.

Stage 8 illustrates a state after a third metal layer 1430 is formed (e.g., disposed) the dielectric layer 1404 and in the cavities 1405. The third metal layer 1430 may be formed using a plating process. The plating process may form vias in the cavities 1405. The third metal layer 1430 may include one or more metal layers (e.g., seed layer and metal layer). In some implementations, the third metal layer 1430 may have a thickness of about 10-16 micrometers (μm).

Stage 9 illustrates a state after a dielectric layer 1406 is formed (e.g., disposed) over the dielectric layer 1404 and the third metal layer 1430.

Stage 10, as shown in FIG. 14C, illustrates a state after one or more cavities 1407 have been formed in the dielectric layer 1406. An etching process, such as laser ablation or photo etching process may be used to form the cavities 1407.

Stage 11 illustrates a state after a fourth metal layer 1440 is formed (e.g., disposed) the dielectric layer 1406 and in the cavities 1407. The fourth metal layer 1440 may be formed using a plating process. The plating process may form vias in the cavities 1407. The fourth metal layer 1440 may include one or more metal layers (e.g., seed layer and metal layer). In some implementations, the third metal layer 1430 and the fourth metal layer 1440 may include interconnects that form one or more inductors. In some implementations, the fourth metal layer 1440 may have a thickness of about 10-16 micrometers (μm).

Stage 12 illustrates a state after a dielectric layer 1408 is formed (e.g., disposed) over the dielectric layer 1406 and the fourth metal layer 1440.

Stage 13, as shown in FIG. 14D, illustrates a state after one or more cavities 1409 have been formed in the dielectric layer 1408 An etching process, such as laser ablation or photo etching process may be used to form the cavities 1409.

Stage 14 illustrates a state after an underbump metallization (UBM) layer 1450 is formed (e.g., disposed) over the dielectric layer 1408 and in the cavities 1409. The UBM layer 1450 may be formed using a plating process. The UBM layer 1450 may include one or more metal layers (e.g., seed layer and metal layer).

Stage 15 illustrates a state after solder interconnects 1460 are provided over the UBM layer 1450, and the wafer is singulated (e.g., sliced, diced) into individual integrated devices. The solder interconnects 1460 may be solder balls. In this example, the singulation of the wafer produces a first integrated device 1470 and a second integrated device 1480, each integrated device having a different design. Despite the first integrated device 1470 and the second integrated device 1480 having separate designs with different pattern densities, both integrated devices have approximately the same metal layer thickness for at least the third and/or fourth metal layers (e.g., M3 and M4). It is noted that in some implementations, the singulation of the wafer may produce several integrated devices with the same designs having uniform metal layer thickness across several metal layers. Once the wafer has been singulated, the first integrated device 1470 and the second integrated device 1480 may be coupled to a board (e.g., printed circuit board) and integrated into a device (e.g., phone).

Exemplary Flow Diagram of a Method for Fabricating an Integrated Device with Uniform Metal Layer Thickness in Each Metal Layer

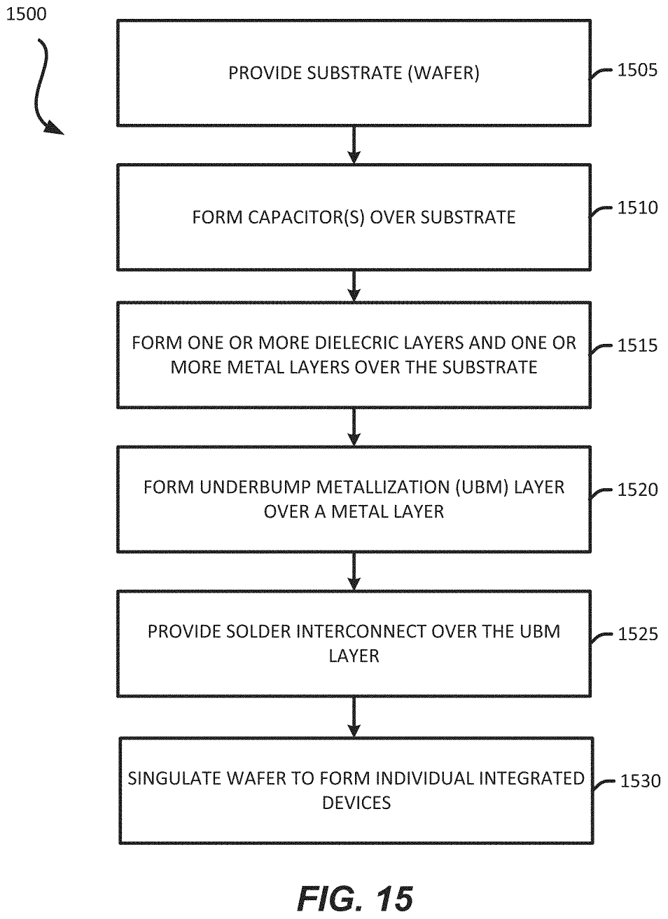

FIG. 15 illustrates an exemplary flow diagram of a method 1500 for fabricating an integrated device with uniform metal layer thickness in each metal layer. In some implementations, the method 1500 of FIG. 15 may be used to fabricate any of the integrated devices described in the disclosure.

It should be noted that the sequence of FIG. 15 may combine one or more processes in order to simplify and/or clarify the method fabricating an integrated device. The integrated device may include at least one capacitor and at least one inductor. In some implementations, the order of the processes may be changed or modified.

The method provides (at 1505) a substrate (202). The substrate may include glass or silicon. The substrate may be a wafer. An example of providing a substrate is described at stage 1 of FIG. 14A.

The method forms (at 1510) at least one capacitor over the substrate. The capacitor may be defined by several metal layers and a high K dielectric layer. In some implementations, forming the capacitor includes forming a first metal layer (1410) over the substrate (202), forming a metal layer (240) and a high K dielectric layer (250), and forming a second metal layer (1420) over the high K dielectric layer (250). The metal layers may be formed using a plating process. The metal layers may include one or more metal layers (e.g., seed layer and metal layer). Forming a capacitor may also include forming dielectric layers between metal layers. An example of forming a capacitor is described at stages 2 through 9 of FIGS. 14A-14B.

The method forms (at 1515) one or more dielectric layers and one or more metal layers over the substrate. Examples of forming dielectric layers and metal layers are described in stage 6 through stage 12 of FIGS. 14B-14D. The one or more metal layers may have approximately the same thickness. Forming the metal layers may include forming a third metal layer (e.g., M3) and a fourth metal layer (M4). In some implementations, the third metal layer and the fourth metal layer include interconnects that form and define one or more inductors.

The method forms (at 1520) an underbump metallization (UBM) layer (1450) over a metal layer (e.g., M4). The UBM layer may be formed using a plating process. The UBM layer may include one or more metal layers (e.g., seed layer and metal layer). Examples of forming an UBM layer is described at stages 13 and 14 of FIG. 14D.

The method provides (at 1525) solder interconnects (1460) over the UBM layer. The solder interconnects may be solder balls. An example of providing solder interconnects is described at stage 15 of FIG. 14D.

The method singulates (at 1530) the wafer to produce a plurality of integrated devices having uniform metal layer thickness in each metal layer. Singulating a wafer may include using a laser and/or a saw to slice and dice the wafer. In some implementations, the singulation of the wafer may produce a first integrated device 1470 and a second integrated device 1480, each integrated device having a different design. It is noted that in some implementations, the singulation of the wafer may produce several integrated devices with the same designs having uniform metal layer thickness across several metal layers. An example of the singulation of a wafer is described at stage 15 of FIG. 14D.

### Exemplary Electronic Devices

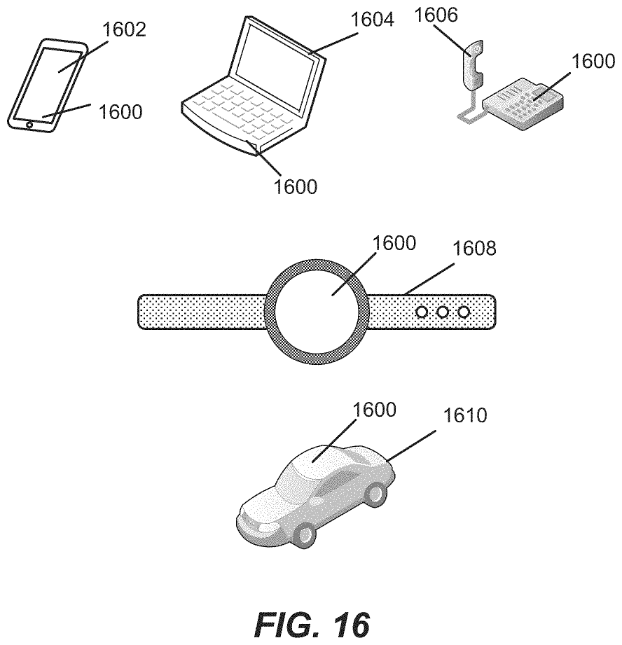

FIG. 16 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). The integrated device, integrated circuit (IC) package, integrated circuit (IC) device, semiconductor device, integrated circuit, die, interposer, package, package-on-package (PoP), System in Package (SiP), System on Chip (SoC), and/or may be formed from a wafer that is diced or singulated. For example, a mobile phone device 1602, a laptop computer device 1604, a fixed location terminal device 1606, a wearable device 1608, or automotive vehicle 1610 may include a device 1600 as described herein. The device 1600 may be, for example, any of the devices and/or integrated circuit (IC) packages described herein. The devices 1602, 1604, 1606 and 1608 and the vehicle 1610 illustrated in FIG. 16 are merely exemplary. Other electronic devices may also feature the device 1600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 2-13, 14A-14D, and/or 15-16 may be rearranged and/or combined into a single component, process, feature or function or embodied in several components, processes, or functions. Additional elements, components, processes, and/or functions may also be added without departing from the disclosure. It should also be noted FIGS. 2-13, 14A-14D, and/or 15-16 and its corresponding description in the present disclosure is not limited to dies and/or ICs. In some implementations, FIGS. 2-13, 14A-14D, and/or 15-16 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. As an example, a first component may be over a second component, even when there are one or more components between the first component and the second component. The term “about ‘value X’”, or “approximately value X”, as used in the disclosure means within 10 percent of the ‘value X’. For example, a value of about 1 or approximately 1, would mean a value in a range of 0.9-1.1. In another example, values that are approximately the same may mean that values are within 10 percent of one another.

In some implementations, an interconnect is an element or component of a device or package that allows or facilitates an electrical connection between two points, elements and/or components. In some implementations, an interconnect may include a trace, a via, a pad, a pillar, a redistribution metal layer, and/or an under bump metallization (UBM) layer. In some implementations, an interconnect is an electrically conductive material that may be configured to provide an electrical path for a signal (e.g., a data signal, ground or power). An interconnect may be part of a circuit. An interconnect may include more than one element or component. An interconnect may be defined by one or more interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An integrated device comprising:
a substrate;
a third plurality of interconnects formed on a third metal layer,
wherein the third metal layer is located over the substrate,
wherein the third metal layer has a third pattern density;
wherein the third plurality of interconnects has a third thickness that is approximately the same for all interconnects of the third plurality of interconnects, and
a fourth plurality of interconnects formed on a fourth metal layer,
wherein the fourth metal layer is located over the third metal layer,
wherein the fourth metal layer has a fourth pattern density,
wherein the fourth pattern density is different than the third pattern density,
wherein the fourth plurality of interconnects has a fourth thickness that is approximately the same for all interconnects of the fourth plurality of interconnects; and
at least one dielectric layer formed over the substrate.

2. The integrated device of claim 1,
wherein the integrated device is from a wafer comprising a plurality of integrated devices,
wherein the third thickness of the third plurality of interconnects for all integrated devices from the plurality of integrated devices, is within about 2 micrometers (μm) of one another, and
wherein the fourth thickness of the fourth plurality of interconnects for all integrated devices from the plurality of integrated devices, is within about 2 micrometers (μm) of one another.

3. The integrated device of claim 1,
wherein the integrated device is from a wafer comprising a plurality of integrated devices,
wherein the third pattern density of the third plurality of interconnects for all integrated devices from the plurality of integrated devices, is within about two percent (2%) of one another, and
wherein the fourth pattern density of the fourth plurality of interconnects for all integrated devices from the plurality of integrated devices, is within about two percent (2%) of one another.

4. The integrated device of claim 1, wherein the third thickness and the fourth thickness are each about 10 micrometers (μm) to 16 micrometers (μm).

5. The integrated device of claim 1, wherein the integrated device is from a wafer comprising a plurality of first integrated devices and a plurality of second integrated devices.

6. The integrated device of claim 1, wherein portions of the third plurality of interconnects and portions of the fourth plurality of interconnects define at least one inductor.

7. The integrated device of claim 6, further comprising at least one capacitor coupled to the inductor.

8. The integrated device of claim 7, wherein the at least one capacitor is defined on at least a first metal layer of the integrated device.

9. The integrated device of claim 1, further comprising a first metal layer and a second metal layer,
wherein the first metal layer is a M1 layer of the integrated device, and
wherein the second metal layer is a M2 layer of the integrated device.

10. The integrated device of claim 9,
wherein the third metal layer is a M3 layer of the integrated device, and
wherein the fourth metal layer is a M4 layer of the integrated device.

11. The integrated device of claim 1, wherein the integrated device is configured to operate as a filter.

12. The integrated device of claim 11, wherein the integrated device is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

13. An apparatus comprising:
a substrate;
means for capacitance coupled to the substrate; and
means for inductance configured to be electrically coupled to the means for capacitance, the means for inductance comprising:
a third plurality of interconnects formed on a third metal layer,
wherein the third metal layer is located over the substrate,
wherein the third plurality of interconnects has a third thickness, and
wherein the third metal layer has a third pattern density, and
a fourth plurality of interconnects formed on a fourth metal layer,
wherein the fourth metal layer is located over the third metal layer,
wherein the fourth plurality of interconnects has a fourth thickness,
wherein the fourth metal layer has a fourth pattern density, and
wherein the fourth pattern density is different than the third pattern density.

14. The apparatus of claim 13,
wherein the substrate, the means for capacitance, and the means for inductance are part of an integrated device from a wafer comprising a plurality of integrated devices,
wherein the third thickness of the third plurality of interconnects for all integrated devices from the plurality of integrated devices, is within about 2 micrometers (μm) of one another, and
wherein the fourth thickness of the fourth plurality of interconnects for all integrated devices from the plurality of integrated devices, is within about 2 micrometers (μm) of one another.

15. The apparatus of claim 13,
wherein the substrate, the means for capacitance, and the means for inductance are part of an integrated device from a wafer comprising a plurality of integrated devices,
wherein the third pattern density of the third plurality of interconnects for all integrated devices from the plurality of integrated devices, is within about two percent (2%) of one another,
wherein the fourth pattern density of the fourth plurality of interconnects for all integrated devices from the plurality of integrated devices, is within about two percent (2%) of one another,

16. The apparatus of claim 13, wherein the third thickness and the fourth thickness are each from 10 micrometers (μm) to 16 micrometers (μm).

17. The apparatus of claim 13, wherein the substrate, the means for capacitance, and the means for inductance are part of an integrated device from a wafer comprising a plurality of first integrated devices and a plurality of second integrated devices.

18. The apparatus of claim 13, further comprising a first metal layer and a second metal layer over the substrate,
wherein the first metal layer is a M1 layer of the apparatus,
wherein the second metal layer is a M2 layer of the apparatus,
wherein the third metal layer is a M3 layer of the apparatus, and
wherein the fourth metal layer is a M4 layer of the apparatus.

19. The apparatus of claim 13, wherein the means for capacitance and the means for inductance are configured to operate as a means for filtering.

20. The apparatus of claim 13, wherein the apparatus includes an integrated passive device (IPD).

21. A wafer comprising:
a plurality of first integrated devices, the first integrated device having a first design, wherein each first integrated device comprises:
a first plurality of third interconnects formed on a third metal layer of the wafer; and
a first plurality of fourth interconnects formed on a fourth metal layer of the wafer; and
a plurality of second integrated devices, the second integrated device having a second design that is different than the first design, wherein each second integrated device comprises:
a second plurality of third interconnects formed on the third metal layer of the wafer; and
a second plurality of fourth interconnects formed on the fourth metal layer of the wafer,
wherein the first plurality of third interconnects for each of the first integrated devices and the second plurality of third interconnects for each of the second integrated devices, have a third thickness that is approximately the same, and
wherein the third metal layer of the first integrated device has a different design than the third metal layer of the second integrated device.

22. The wafer of claim 21, wherein the first plurality of fourth interconnects for each of the first integrated devices and the second plurality of fourth interconnects for each of the second integrated devices, have a fourth thickness that is approximately the same.

23. The wafer of claim 21, wherein the fourth metal layer of the first integrated device has a different design than the fourth metal layer of the second integrated device.

24. The wafer of claim 21, wherein at least some of the interconnects from (i) the first plurality of third interconnects and (ii) the first plurality of fourth interconnects, define at least one inductor for the first integrated device.

25. The wafer of claim 21, wherein the first integrated device has a pattern density for the third metal layer that is different than a pattern density for the third metal layer of the second integrated device.

26. The wafer of claim 21, wherein the first integrated device has a pattern density for the fourth metal layer that is different than a pattern density for the fourth metal layer of the second integrated device.

27. A device comprising:
a board;
a first integrated device coupled to the board, the first integrated device comprising:
a first substrate;
a first plurality of third interconnects formed on a third metal layer of the first integrated device; and
a first plurality of fourth interconnects formed on a fourth metal layer on the first integrated device; and
a second integrated device coupled to the board, the second integrated device comprising:
a second substrate;
a second plurality of third interconnects formed on a third metal layer of the second integrated device; and
a second plurality of fourth interconnects formed on a fourth metal layer of the second integrated device;
wherein the first plurality of third interconnects for the first integrated device and the second plurality of third interconnects for second integrated device, have a third thickness that is approximately the same, and
wherein the third metal layer of the first integrated device has a different design than the third metal layer of the second integrated device.

28. The device of claim 27, wherein the first plurality of fourth interconnects for the first integrated device and the second plurality of fourth interconnects for second integrated device, have a fourth thickness that is approximately the same.

29. The device of claim 27,
wherein at least some of the interconnects from (i) the first plurality of third interconnects and (ii) the first plurality of fourth interconnects, define at least one inductor for the first integrated device, and
wherein at least some of the interconnects from (i) the second plurality of third interconnects and (ii) the second plurality of fourth interconnects, define at least one inductor for the second integrated device.

30. The device of claim 27, wherein the device is configured to operate as a filter.
